(19) United States
(12) Patent Application Publication
(10) Pub. No.: US 2025/0285939 A1
(43) Pub. Date: Sep. 11, 2025

(54) COMPACT FORM FACTOR FLUID FLOW REGULATOR

(71) Applicant: Intel Corporation, Santa Clara, CA (US)

(72) Inventors: Devdatta P. KULKARNI, Portland, OR (US); Brian S. JARRETT, Hillsboro, OR (US); John C. GULICK, Portland, OR (US); Jeffrey KING, Portland, OR (US); Paul C. GEORGE, Beaverton, OR (US)

(21) Appl. No.: 19/214,882

(22) Filed: May 21, 2025

Related U.S. Application Data
(60) Provisional application No. 63/650,333, filed on May 21, 2024.

(51) Int. Cl. H01L 23/473

(52) U.S. Cl. CPC H01L 23/473

(57) ABSTRACT

A fluid flow regulator assembly useful for coolant systems for semiconductor devices is provided. Assemblies and systems comprising one or more fluid flow regulators are also provided.

### PRIORITY

This application is a nonprovisional application that is based on, and claims the benefit of priority of, U.S. Patent Application No. 63/650,333, filed May 21, 2024.

### FIELD

Descriptions are generally related to thermal management of semiconductor chips, and more particularly, descriptions are related to fluid flow regulation in thermal management solutions.

### BACKGROUND

Semiconductor chips are central to intelligent devices and systems, such as personal computers, laptops, tablets, phones, servers, and other consumer and industrial products and systems. As semiconductor chips become smaller and more powerful, heat management presents additional challenges. Overheating in semiconductor chips can cause performance decline and semiconductor chip failure.

Thermal management solutions for semiconductor chips include, for example, metallic heat spreaders, air cooling systems, and/or liquid cooling systems. Thermal solutions can be entirely air cooling systems, liquid-to-air cooling solutions, combined liquid and air cooling systems, or liquid cooling systems. For cooling systems that employ a liquid, the liquid can be present in two phases (e.g., a gas and a fluid) during cooling system operation.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIGS. 1A-1B illustrate a fluid flow regulator that can be used in computing systems.

FIG. 2 illustrates an assembly comprising a cold plate and fluid flow regulators.

FIG. 3 provides an exemplary fluid cooling system for semiconductor chips.

FIG. 4 shows a data center architecture in which liquid cooling and fluid flow regulators can be employed.

FIG. 5 provides a further example of a computing system in which liquid cooling and fluid flow regulators can be employed.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Operations can be performed by semiconductor processing and/or testing equipment, including computer systems that run testing protocols and operate aspects of testing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Direct liquid cooling (DLC) can be used for cooling computation devices, especially for cooling components of large-scale computing systems, such as, for example, data centers. Direct liquid cooling systems can employ, for example, cold plates or other devices that are capable of removing heat from components of computing systems. A fluid coolant can be circulated through, for example, channels in cold plates and then circulated through a heat exchanger which cools the fluid coolant. The DLC can be a pumped two-phase (P2P) liquid cooling system in which

A direct liquid cooling P2P cooling solution can have a cold plate array in which a fluid outlet of each array can exhibit about 70 to 80% vapor at full thermal design power (TDP) (where about indicates plus or minus 10% of a value). Exit vapor quality depends on the total heat load on the array (single cold plate or multiple cold plates in series) and the fluid flowing through each array. In a clustered system, either at server or rack or cluster level, there can be multiple arrays in parallel. Based on, for example, workloads and/or virtual machine (VM) utilization, each array can have different heat load management requirements. In a two phase (2P) liquid cold plate array, a significant pressure drop can result from the amount of vapor that is generated. Vapor generation rate is directly proportional to the heat load on each array. Variable heat loads on each array can create instability in the flows and may result in dry out issues in certain arrays, leading to thermal throttling or complete shutdown of a server and/or cluster (depending on the severity of the fluid flow restriction). Constant fluid flow through each array irrespective of heat load in the given loop or loops in the system and/or cluster is critical for maintaining system stability.

The pumped 2-phase cooling solution can create a situation where the vaporizing fluid creates backpressure. To have proper flow distribution across the flow network for each parallel loop, flow regulators, such as, spring-loaded flow regulators, can be incorporated into the fluid-based heat management system. Flow regulators can provide a constant volumetric flow rate regardless of the amount of fluid vaporization in a cold plate or cold plate array having multiple cold plates in series.

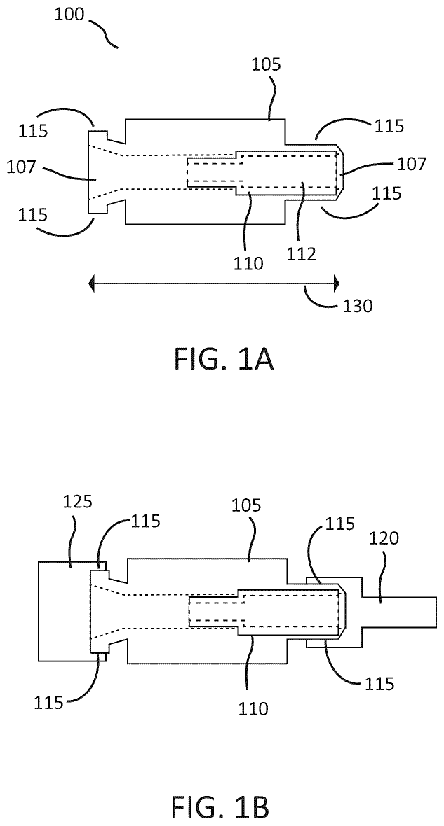

FIGS. 1A and 1B illustrate a fluid flow regulator assembly 100 that can be used in a fluid coolant system for cooling computation devices. The flow regulator assembly 100 is illustrated as sliced through on a center line so that the inside can be viewed. The fluid flow regulator assembly 100 can be integrated into locations in a coolant loop such as, connected to piping adapters, manifolds, manifold assemblies, cold plate inlet manifolds, cold plate arrays, and/or other fluid cooling interfaces that couple with heat producing components. The fluid flow regulator assembly 100 can comprise a body 105 having an internal cavity 107 (shown in FIG. 1A as a dashed line), a fluid flow regulator 110, and fluid conduit attachment regions 115. Optionally the body 105 is a unitary part that can be comprised of a metallic material, such as for example, copper, aluminum, or an alloy comprising, copper, zinc, lead, tin, aluminum, and/or manganese. A unitary body 105 can be one that does not include brazing or other mechanisms that join parts together. Alternately the body 105 can be one in which parts are joined together by brazing or other mechanisms. For example, fluid conduit attachment regions 115 can be attached through brazing. The unitary body 105 can have a length (illustrated by arrow 130) that is about 112 mm (where about indicates plus or minus 10% of a value) or a length that is between 110 and 200 mm. The cavity 107 forms a channel through which fluid can flow in and out of the fluid flow regulator assembly 100 and the flow regulator 110 is housed in the cavity 107. The flow regulator 110 also comprises a flow region 112 (indicated by the dashed lines) through which a fluid can flow. The flow regulator 110 can be, for example, a flow regulator comprising a spring and/or piston mechanism, or an orifice constant area constrictor. Flow regulators can provide a constant volumetric flow rate regardless of the amount of fluid vaporization in a cooling system. Flow regulators 110 can be manufactured having a variety of flow characteristics. The flow regulator 110 can be a replaceable flow control cartridge that includes a field-serviceable snap ring that allows a flow control cartridge to be changed at an installation site, for example it can be swapped out for a flow control cartridge having different flow characteristics.

In FIG. 1B, the fluid flow regulator assembly 100 of FIG. 1A is shown with exemplary fluid conduit attachment devices 120 and 125. The fluid conduit attachment regions 115 can comprise, for example, a threaded region that allows for attaching fluid conduit attachment devices 120 and 125 having a mating threaded region. The fluid conduit attachment devices 120 and 125 can be, for example, barb fittings, in-line connectors, metal fittings for connecting to metal coolant lines, and/or quick disconnect devices, for a fluid conduit. The fluid conduit attachment devices 120 and 125 can be, for example, 5400 refrigerant connections to male 45 degrees flare. Other fitting types are possible. By switching the fluid flow regulator assembly 100, the same coolant loop design can be used, for example, for 1-2 kW central processing unit (CPU) servers or greater than 10 KW GPU/accelerator servers.

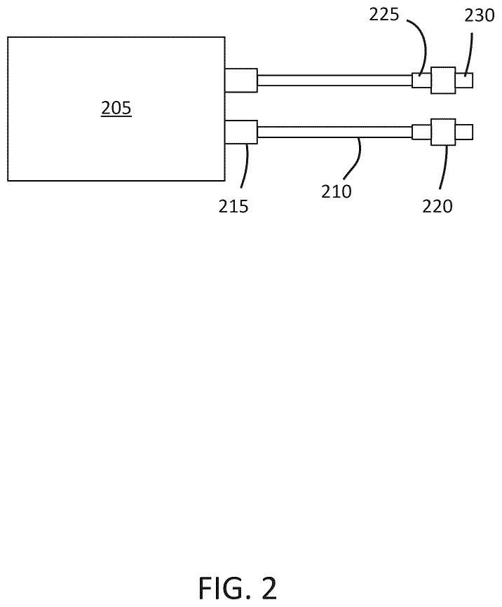

FIG. 2 provides an exemplary installation scheme for a fluid flow regulator assembly 220. The fluid flow regulator assembly 220 can be, for example, the fluid flow regulator assembly 100 of FIG. 1A. In FIG. 2, a cold plate 205 for a computing device comprising one or more semiconductor chips (not shown) comprises flow channels (not shown) for a fluid to flow. The cold plate 205 can be comprised of a metallic material, such as copper or aluminum, a combination of metallic materials in layers, and/or a combination of metallic materials as an alloy. Fluid conduits 210 are attached to the cold plate through attachment mechanisms 215. The fluid conduits 210 can be, for example, hoses. The fluid conduits 210 are attached also to fluid flow regulator assemblies 220. The attachment can be through, for example a hose barb 225. The cold plate assembly of FIG. 2 can also include a coolant system attachment device 230, that can be, for example, a 5400 refrigerant connector.

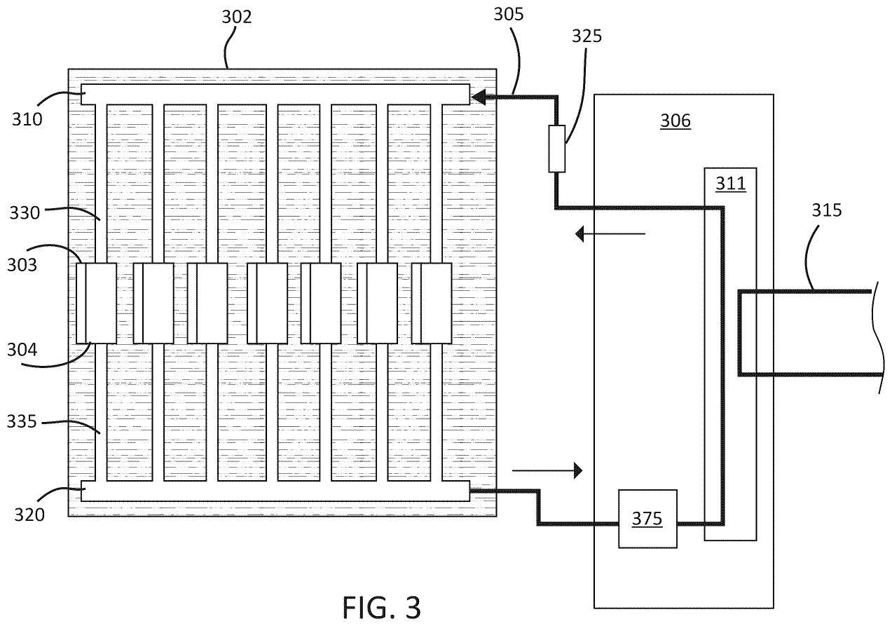

A fluid coolant system can be, for example, a pumped two phase (2P) liquid cold plate array. FIG. 3 shows a data center implementation that includes an array of high performance packaged semiconductor chips 303 (e.g., central processing units (CPUs), graphics processing units (GPUs), Artificial Intelligence/Machine Learning (AI/ML) accelerators, high performance switch cores, high performance application specific integrated circuits (ASICs), etc.). The semiconductor chips 303 can be assembled within and/or upon a common mechanical package or substrate such one or more printed circuit boards, one or more rack mountable units (e.g., one or more 1U (one unit of space in a rack server) or 2U (two rack units of vertical space) form factor rack mountable server(s). An array of high performance packaged semiconductor chips 303 are cooled with corresponding cold plates 304. FIG. 3 depicts one cold plate 304 per semiconductor chip 303 package across an array of semiconductor chip 303 packages. However, a single cold plate 304 can be thermally coupled to more than one semiconductor chip 303 package and/or multiple cold plates 304 can be coupled to a single semiconductor chip 303 package. The cold plates 304 comprise fluid channels (not shown) that are capable of allowing a fluid to circulate.

In FIG. 3, a fluid flow regulator assembly 325 can be inserted in and/or mechanically integrated into a cooled fluid conduit 305 that is between ingress manifold 310 and heat exchanger 311 that can be external from the cold plate array mechanical package and/or substrate. A fluid flow regulator assembly 325 can be integrated along other locations of the cooled fluidic channel 305. For example, the fluid flow regulator assembly 325 can be located within a cold plate array assembly 302 and/or upon a cold plate array substrate. The fluid flow regulator assembly 325 can be also located within a fluid ingress manifold 310. Multiple instances of a fluid flow regulator assembly 325 can be located at outputs of an ingress manifold 310 or along the ingress conduits 330 to a cold plate 304. A fluid flow regulator assembly 325 can also be coupled to a fluid egress 335 of a cold plate 304. A fluid flow regulator assembly 325 can also be fitted to any piping structure and/or adaptor along the cooled fluid line from the heat exchanger 311 to a cold plate 304. The fluid flow regulator assembly 325 can be the fluid flow regulator assembly of FIG. 3.

Each cold plate 304 can receive cooled fluid that is pumped into the cold plate(s) 304 downstream from a cooling distribution unit (CDU) 306 by a pump 375. In the particular system of FIG. 3, cooled fluid is pumped from the CDU 306 and is directed to an ingress manifold 310 that divides the cooled fluid into separate cooled fluid streams that are directed along cooled fluid ingress conduits 330 that feed respective cold plates 304. For illustrative ease FIG. 3 shows one cold plate 304 per cooled fluid stream that emanates from the ingress manifold 310. However, in practice, multiple cold plates 304 can be coupled in series so that a single cooled fluid stream first flows into a first cold plate, then flows into a second cold plate (after being warmed somewhat from the first cold plate), etc.

As cooled fluid flows through a cold plate 304 it receives heat being generated by the operating semiconductor chip(s) 303 within the chip package(s) that the cold plate 304 is thermally coupled to and is emitted as warmed fluid along a warmed fluid egress conduit 335. Multiple egress conduits 335 are coupled to an egress manifold 320 which combines the separate warmed fluid streams from the cold plates 304 and directs a combined warmed fluid flow back to the CDU 306.

The CDU 306 includes a pump 375 and heat exchanger 311. The heat exchanger 311 transfers heat from the warmed fluid to another liquid cooling loop 315 (the heat is subsequently removed from the liquid in loop 315 and returned to the heat exchanger 311 as cooled fluid). The removal of the heat from the warmed fluid flowing from the egress manifold 110 cools the fluid, which creates cooled fluid that is then pumped by the CDU 306 to the ingress manifold 310 as cooled fluid. The process then repeats.

Cooling equipment other than a CDU 306 having a heat exchanger 311 can also be used to cool the warmed fluid and return it to the ingress manifold 310 as cooled fluid (e.g., an active refrigeration unit). Such cooling equipment, whether a CDU 306, active refrigeration unit, or other cooling device, can more generally be referred to as a “chiller.”

In the particular system of FIG. 3, when one or more of the high performance packaged semiconductor chips 303 are operating at higher workloads and therefore emitting more heat, the coolant liquid with their respective cold plate(s) can boil resulting in vaporization. Depending on the specific design of the cooling system, the vapor is condensed (cooled) back into a liquid within the cold plate(s) 304 and/or downstream from the cold plates 304 (e.g., with heat sinks on the cold plate and/or the egress conduits or manifold, or other region.)

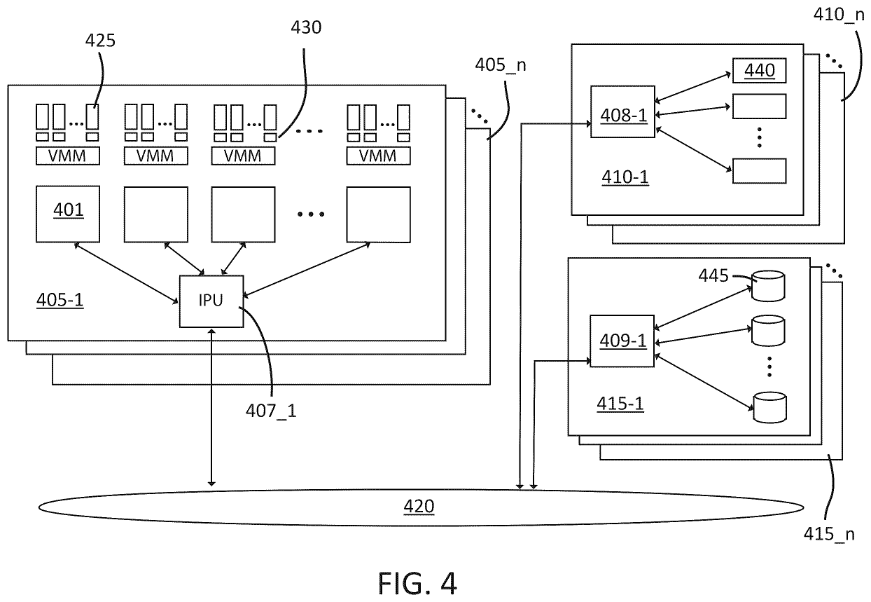

FIG. 4 shows a data center environment in which “infrastructure” tasks are offloaded from traditional general purpose “host” CPUs (where application software programs are executed) to an infrastructure processing unit (IPU) or data processing unit (DPU) any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.). Remote clients invoke/use these applications through temporary network sessions/connections that are established by the data center between the clients and the applications. In order to support the network sessions and/or the applications' functionality, certain underlying computationally intensive and/or trafficking intensive functions (“infrastructure” functions) are performed. Examples of infrastructure functions include routing layer functions (e.g., IP routing), transport layer protocol functions (e.g., TCP), encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), and distributed computing remote memory access functions.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators.

In FIG. 4, the infrastructure functions are migrated to an infrastructure processing unit (IPU) 407_1 to 407_n, 408_1 to 408_n, and 409_1 to 409_n. FIG. 4 depicts an exemplary data center environment that integrates IPUs 407_1 to 407_n, 408_1 to 408_n, and 409_1 to 409_n. to offload infrastructure functions from the host CPUs 401 as described above. The exemplary data center environment can include pools of CPU units 405 that execute the end-function application software programs 425 that are typically invoked by remotely calling clients. The data center also includes separate memory pools 410_1 to 410_n and mass storage pools 415_1 to 415_n to assist the executing applications. The CPU pools 405_1 to 405_n, memory pools 410_1 to 410_n and mass storage pools 415_1 to 415_n, are coupled by one or more networks 420. The memory pools 410_1 to 410_n comprise a plurality of memory units 440 managed by an IPU 408_1 to 408_n. The mass storage pools 415_1 to 415_n comprise a plurality of mass storage units 445 managed by an IPU 409_1 to 409_n.

The CPU pools 405_1 to 405_n, have an IPU 407_1 to 407_n on its front end or network side. Here, each IPU 407_1 to 407_n can perform pre-configured infrastructure functions on the inbound (request) packets it receives from the network 420 before delivering the requests to its respective pool's end function (e.g., executing application software in the case of the CPU pool 405_1, memory in the case of memory pool 410_1 and storage in the case of mass storage pool 415_1).

As the end functions send certain communications into the network 420, the IPUs 407_1 to 407_n perform pre-configured infrastructure functions on the outbound communications before transmitting them into the network 420. The communication between the IPU 407_1 and the CPUs 401 in the CPU pool 405_1 can transpire through a network (e.g., a multi-nodal hop Ethernet network) and/or more direct channels (e.g., point-to-point links) such as Compute Express Link (CXL), Advanced Extensible Interface (AXI), Open Coherent Accelerator Processor Interface (OpenCAPI), or Gen-Z.

Depending on implementation, one or more CPU pools 405_1 to 405_n, memory pools 410_1 to 410_n, mass storage pools 415_1 to 415_n and network 420 can exist within a single chassis, e.g., as a traditional rack mounted computing system (e.g., server computer). In a disaggregated computing system implementation, one or more CPU pools 405_1 to 405_n, memory pools 410_1 to 410_n, and mass storage pools 415_1 to 415_n are separate rack mountable units (e.g., rack mountable CPU units, rack mountable memory units, rack mountable mass storage units).

In various embodiments, the software platform on which the applications 425 are executed include a virtual machine monitor (VMM), or hypervisor, that instantiates multiple virtual machines (VMs). Operating system (OS) instances 430 respectively execute on the VMs and the applications execute on the OS instances. Alternatively or combined, container engines (e.g., Kubernetes container engines) respectively execute on the OS instances 430.

The electronic boards/components of the data center components of FIG. 4 can be liquid cooled with a system having a flow regulator assembly, which can be the fluid flow regulator assemblies of FIGS. 1A-1B. The cooling system can be, for example, a pumped fluid cooling system, such as, the system of FIG. 3, and the cooling units for one or more semiconductor chips (e.g., CPUs, IPUs, and memory systems) can be the assembly of FIG. 2.

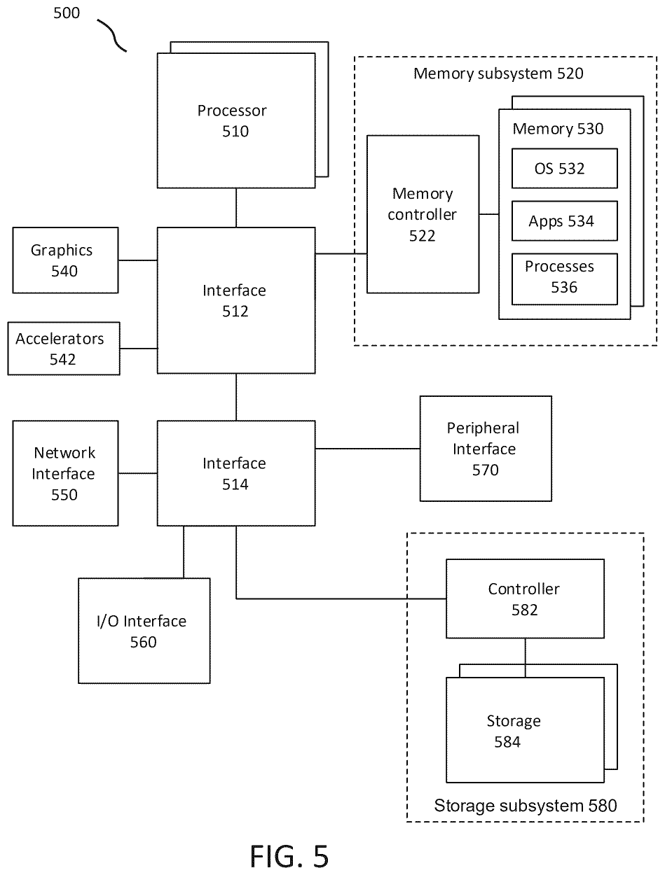

Semiconductor devices (or chips) can be any of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 5. The semiconductor chip packages described herein generally can be part of various larger package structures and configurations and the foregoing examples are not meant to limit the types of assemblies that are possible.

Circuit boards can be, for example, a mother board, a logic board, a mainboard, a system board, and/or a printed circuit board.

FIG. 5 depicts an additional example computing system. A computing system 500 can include more, different, or fewer features than the ones described with respect to FIG. 5. One or more computing parts of the system of FIG. 5 can be liquid cooled using the fluid flow regulator assemblies of FIGS. 1A-1B. The cooling system can be, for example, a pumped fluid cooling system, such as, the system of FIG. 3, and the cooling units for one or more semiconductor chips (e.g., CPUs, IPUs, and memory systems) can be the assembly of FIG. 2.

Computing system 500 includes processor 510, which provides processing, operation management, and execution of instructions for system 500. Processor 510 can include any type of microprocessor, CPU (central processing unit), GPU (graphics processing unit), processing core, or other processing hardware to provide processing for system 500, or a combination of processors or processing cores. Processor 510 controls the overall operation of system 500, and can be or include, one or more programmable general-purpose or special-purpose microprocessors, DSPs, programmable controllers, ASICs, programmable logic devices (PLDs), or the like, or a combination of such devices.

In one example, system 500 includes interface 512 coupled to processor 510, which can represent a higher speed interface or a high throughput interface for system components needing higher bandwidth connections, such as memory subsystem 520 or graphics interface components 540, and/or accelerators 542. Interface 512 represents an interface circuit, which can be a standalone component or integrated onto a processor die. Where present, graphics interface 540 interfaces to graphics components for providing a visual display to a user of system 500. In one example, the display can include a touchscreen display.

Accelerators 542 can be a fixed function or programmable offload engine that can be accessed or used by a processor 510. For example, an accelerator among accelerators 542 can provide data compression (DC) capability, cryptography services such as public key encryption (PKE), cipher, hash/authentication capabilities, decryption, or other capabilities or services. In some cases, accelerators 542 can be integrated into a CPU socket (e.g., a connector to a motherboard (or circuit board, printed circuit board, mainboard, system board, or logic board) that includes a CPU and provides an electrical interface with the CPU). For example, accelerators 542 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 542 can provide multiple neural networks, CPUs, processor cores, general purpose graphics processing units, or graphics processing units can be made available for use by artificial intelligence (AI) or machine learning (ML) models.

Memory subsystem 520 represents the main memory of system 500 and provides storage for code to be executed by processor 510, or data values to be used in executing a routine. Memory subsystem 520 can include one or more memory devices 530 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 530 stores and hosts, among other things, operating system (OS) 532 that provides a software platform for execution of instructions in system 500, and stores and hosts applications 534 and processes 536. In one example, memory subsystem 520 includes memory controller 522, which is a memory controller to generate and issue commands to memory 530. The memory controller 522 can be a physical part of processor 510 or a physical part of interface 512. For example, memory controller 522 can be an integrated memory controller, integrated onto a circuit within processor 510.

System 500 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 500 includes interface 514, which can be coupled to interface 512. In one example, interface 514 represents an interface circuit, which can include standalone components and integrated circuitry. In one example, user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB, or other wired or wireless standards-based or proprietary interfaces. Network interface 550 can transmit data to a device that is in the same data center or rack or a remote device, which can include sending data stored in memory.

Some examples of network interface 550 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include additional types of hardware interfaces, such as, for example, interfaces to semiconductor fabrication equipment and/or electrostatic charge management devices.

In one example, system 500 includes storage subsystem 580. Storage subsystem 580 includes storage device(s) 584, which can be or include any conventional medium for storing data in a nonvolatile manner, such as one or more magnetic, solid state, and/or optical based disks. Storage 584 can be generically considered to be a “memory,” although memory 530 is typically the executing or operating memory to provide instructions to processor 510. Whereas storage 584 is nonvolatile, memory 530 can include volatile memory (e.g., the value or state of the data is indeterminate if power is interrupted to system 500). In one example, storage subsystem 580 includes controller 582 to interface with storage 584. In one example controller 582 is a physical part of interface 512 or processor 510 or can include circuits or logic in both processor 510 and interface 514.

A power source (not depicted) provides power to the components of system 500. More specifically, power source typically interfaces to one or multiple power supplies in system 500 to provide power to the components of system 500.

Examples of systems may be implemented in various types of computing, smart phones, tablets, personal computers, and networking equipment, such as switches, routers, racks, and blade servers such as those employed in a data center and/or server farm environment.

### Examples

A device can comprise: a unitary body comprising a cavity that traverses the unitary body in a direction, wherein the cavity is open at a first end of the unitary body and open at a second end of the unitary body, wherein the unitary body comprises a first attachment region at the first end and a second attachment region at the second end, and wherein the unitary body has a dimension along the direction and a length of the dimension is between 110 and 200 mm; and a flow regulator within the cavity of the unitary body wherein the flow regulator is capable of providing a constant volumetric flow rate. The first attachment region can be a threaded region. The unitary body can be one that does not comprise brazing. The device can also comprise a hose barb attached to the unitary body in the first attachment region. The flow regulator can be removably mounted in the cavity of the unitary body.

An assembly can comprise: a cold plate wherein the cold plate has fluid flow channels, a fluid inlet, and a fluid outlet; a first fluid flow line connected to the fluid inlet; a second fluid flow line connected to the fluid outlet; and a first fluid flow regulator assembly comprising: a unitary body comprising a cavity that traverses the unitary body in a direction, wherein the cavity is open at a first end of the unitary body and open at a second end of the unitary body, wherein the unitary body comprises a first attachment region at the first end and a second attachment region at the second end, and wherein the unitary body has a dimension along the direction and a length of the dimension is between 110 and 200 mm; and a flow regulator within the cavity of the unitary body wherein the flow regulator is capable of providing a constant volumetric flow rate, wherein the first fluid flow regulator assembly is operably connected to the first fluid flow line or the second fluid flow line. The assembly can comprise a second fluid flow regulator assembly wherein the first fluid flow regulator assembly can be operably connected to the first fluid flow line and the second fluid flow regulator assembly can be operably connected to the second fluid flow line. The first fluid flow line can be a hose. The first fluid flow regulator assembly can be operably connected to the first fluid flow line through a hose barb. The unitary body can be one that does not comprise brazing. The flow regulator can be removably mounted in the cavity of the unitary body. The first attachment region can be a threaded region. The assembly also can comprise a 5400 refrigerant connector on the second attachment region.

A system can comprise: a coolant distribution unit comprising: a heat exchange unit capable of cooling a coolant fluid, first fluid lines capable of containing a coolant fluid; and a pump capable of circulating a coolant fluid wherein the first fluid lines connect the pump to the heat exchange unit; a second fluid line wherein the second fluid line connects to a first fluid line of the coolant distribution unit; and a fluid flow regulator assembly comprising: a unitary body comprising a cavity that traverses the unitary body in a direction, wherein the cavity is open at a first end of the unitary body and open at a second end of the unitary body, and wherein the unitary body comprises a first attachment region at the first end and a second attachment region at the second end; and a flow regulator within the cavity of the unitary body wherein the flow regulator is capable of providing a constant volumetric flow rate, wherein the fluid flow regulator assembly is connected to the second fluid line. The unitary body can have a dimension along the direction and a length of the dimension can be between 110 and 200 mm. The system also can comprise a cold plate wherein the cold plate comprises fluid flow channels. The first attachment region can be a threaded region. The flow regulator can be removably mounted in the cavity of the unitary body. The system of claim 14 wherein the unitary body does not comprise brazing. The unitary body can be comprised of a metallic material.

Besides what is described herein, various modifications can be made to what is disclosed and implementations without departing from their scope. Therefore, the illustrations and examples herein should be construed in an illustrative, and not a restrictive sense.

What is claimed is:

1. A device comprising:
a unitary body comprising a cavity that traverses the unitary body in a direction, wherein the cavity is open at a first end of the unitary body and open at a second end of the unitary body, wherein the unitary body comprises a first attachment region at the first end and a second attachment region at the second end, and wherein the unitary body has a dimension along the direction and a length of the dimension is between 110 and 200 mm; and
a flow regulator within the cavity of the unitary body wherein the flow regulator is capable of providing a constant volumetric flow rate.

2. The device of claim 1 wherein the first attachment region is a threaded region.

3. The device of claim 1 wherein the unitary body does not comprise brazing.

4. The device of claim 1 also comprising a hose barb attached to the unitary body in the first attachment region.

5. The device of claim 1 wherein the flow regulator is removably mounted in the cavity of the unitary body.

6. An assembly comprising:
a cold plate wherein the cold plate has fluid flow channels, a fluid inlet, and a fluid outlet;
a first fluid flow line connected to the fluid inlet;
a second fluid flow line connected to the fluid outlet; and
a first fluid flow regulator assembly comprising:
a unitary body comprising a cavity that traverses the unitary body in a direction, wherein the cavity is open at a first end of the unitary body and open at a second end of the unitary body, wherein the unitary body comprises a first attachment region at the first end and a second attachment region at the second end, and
wherein the unitary body has a dimension along the direction and a length of the dimension is between 110 and 200 mm; and
a flow regulator within the cavity of the unitary body wherein the flow regulator is capable of providing a constant volumetric flow rate,
wherein the first fluid flow regulator assembly is operably connected to the first fluid flow line or the second fluid flow line.

7. The assembly of claim 6 also comprising a second fluid flow regulator assembly wherein the first fluid flow regulator assembly is operably connected to the first fluid flow line and the second fluid flow regulator assembly is operably connected to the second fluid flow line.

8. The assembly of claim 6 wherein the first fluid flow line is a hose.

9. The assembly of claim 6 wherein the first fluid flow regulator assembly is operably connected to the first fluid flow line through a hose barb.

10. The assembly of claim 6 wherein the unitary body does not comprise brazing.

11. The assembly of claim 6 wherein the flow regulator is removably mounted in the cavity of the unitary body.

12. The assembly of claim 6 wherein the first attachment region is a threaded region.

13. The assembly of claim 6 also comprising a 5400 refrigerant connector on the second attachment region.

14. A system comprising:
a coolant distribution unit comprising: a heat exchange unit capable of cooling a coolant fluid, first fluid lines capable of containing a coolant fluid; and a pump capable of circulating a coolant fluid wherein the first fluid lines connect the pump to the heat exchange unit;
a second fluid line wherein the second fluid line connects to a first fluid line of the coolant distribution unit; and
a fluid flow regulator assembly comprising:
a unitary body comprising a cavity that traverses the unitary body in a direction, wherein the cavity is open at a first end of the unitary body and open at a second end of the unitary body, and wherein the unitary body comprises a first attachment region at the first end and a second attachment region at the second end; and
a flow regulator within the cavity of the unitary body wherein the flow regulator is capable of providing a constant volumetric flow rate,
wherein the fluid flow regulator assembly is connected to the second fluid line.

15. The system of claim 14 wherein the unitary body has a dimension along the direction and a length of the dimension is between 110 and 200 mm.

16. The system of claim 14 also comprising a cold plate wherein the cold plate comprises fluid flow channels.

17. The system of claim 14 wherein the first attachment region is a threaded region.

18. The system of claim 14 wherein the flow regulator is removably mounted in the cavity of the unitary body.

19. The system of claim 14 wherein the unitary body does not comprise brazing.

20. The system of claim 14 wherein the unitary body is comprised of a metallic material.
